(19) United States
(12) Patent Application Publication
(10) Pub. No.: US 2025/0385149 A1
(43) Pub. Date: Dec. 18, 2025

(54) SEMICONDUCTOR PACKAGES AND METHODS FOR MAKING THE SAME

(71) Applicant: JCET STATS ChipPAC Korea Limited, Incheon (KR)

(72) Inventors: SeungHyun LEE, Incheon (KR); YeJin PARK, Incheon (KR); HeeSoo LEE, Incheon (KR)

(21) Appl. No.: 19/235,548

(22) Filed: Jun. 11, 2025

(30) Foreign Application Priority Data
Jun. 12, 2024 (CN) 202410755799.9

(51) Int. Cl. H01L 23/31; H01L 21/56; H01L 23/00

(52) U.S. Cl. CPC H01L 23/3107; H01L 21/565; H01L 24/11; H01L 24/81; H01L 2224/1132; H01L 2224/81815

(57) ABSTRACT

A semiconductor package comprises: a substrate; a semiconductor die mounted on the substrate; an antenna block mounted on the substrate and at a first side of the semiconductor die, wherein the antenna block has a height greater than that of the semiconductor die; an interconnection structure mounted on the substrate and at a second side of the semiconductor die, wherein the first side is different from the second side; and an encapsulant layer formed on the substrate and for encapsulating the semiconductor die but exposing the antenna block and the interconnection structure.

### TECHNICAL FIELD

The present application generally relates to semiconductor devices, and more particularly, to a semiconductor package and a method for making the same.

### BACKGROUND OF THE INVENTION

The semiconductor industry is constantly faced with complex integration challenges as consumers want their electronics to be smaller, faster and higher performance with more and more functionality packed into a single device. One of the solutions is Antenna-in-Package (AiP). AiP is a functional electronic system or sub-system that integrates a semiconductor system and antenna(s) into one package. However, the manufacture efficiency of conventional AiP structures may be not satisfactory.

This invention provides a new AiP structure with improved manufacture efficiency.

### SUMMARY OF THE INVENTION

An objective of the present application is to provide an AiP semiconductor package with an improved manufacture efficiency.

According to an aspect of the present application, a semiconductor package is provided. The semiconductor package comprises: a substrate; a semiconductor die mounted on the substrate; an antenna block mounted on the substrate and at a first side of the semiconductor die, wherein the antenna block has a height greater than that of the semiconductor die; an interconnection structure mounted on the substrate and at a second side of the semiconductor die, wherein the first side is different from the second side; and an encapsulant layer formed on the substrate and for encapsulating the semiconductor die but exposing the antenna block and the interconnection structure.

According to another aspect of the present application, a method for forming a semiconductor package is provided. The method comprises: providing a substrate; mounting a semiconductor die, an antenna block and an interconnection structure on the substrate, wherein the antenna block and the interconnection structure are at a first side and a second side of the semiconductor die, respectively, and the antenna block has a height greater than that of the semiconductor die; and forming an encapsulant layer on the substrate to encapsulate the semiconductor die but expose the antenna block and the interconnection structure.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a cross-sectional view of a semiconductor package according to an embodiment of the present application.

FIG. 1B illustrates a top view of the semiconductor package shown in FIG. 1A according to an embodiment of the present application, without showing the encapsulant layer.

FIGS. 2A to 2G illustrate cross-sectional views of steps for forming a semiconductor package according to an embodiment of the present application.

FIGS. 2H and 2I illustrate cross-sectional views of the step for pressing according to an embodiment of the present application.

FIGS. 3A to 3C illustrate cross-sectional views of steps for forming a semiconductor package according to another embodiment of the present application.

FIG. 3D illustrates a cross-sectional view of a semiconductor package formed with the steps shown in FIGS. 3A to 3C according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

In conventional Antenna-in-Package (AiP) structures, antenna blocks may be implemented using cavity substrates. For such conventional AiP structures, due to the height difference between the antenna block and the substrate, a 3D stencil is usually required for printing solder on the cavity substrate. At the intersection between the antenna block and the substrate, the 3D stencil may include a slope, and an area of the substrate under the slope may not be formed with solder. It can be seen that, the stencil and the printing process for the traditional AiP structure may be complicated and spatially inefficient. Regarding this, the present application introduces a new AiP structure with improved manufacture efficiency.

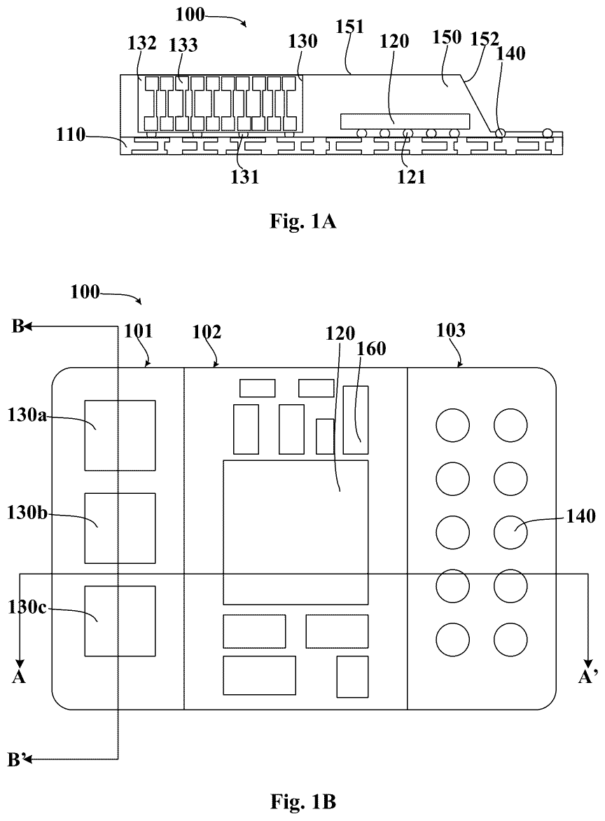

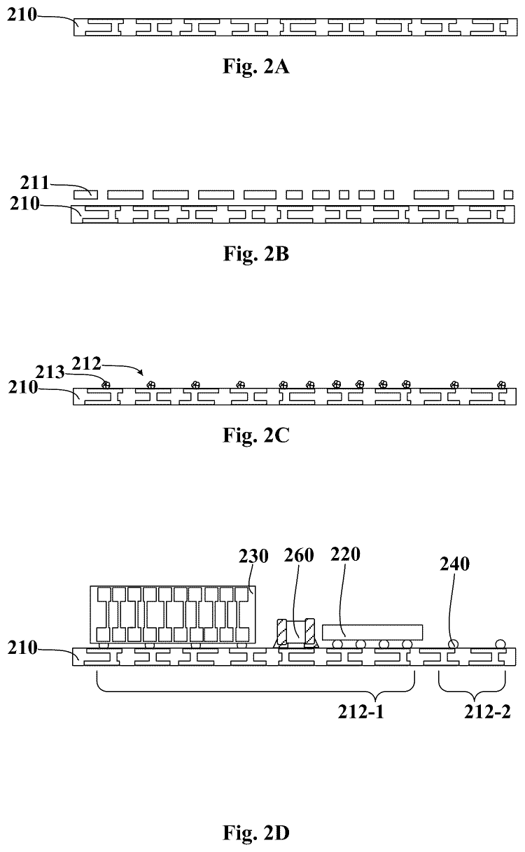

FIGS. 1A and 1B illustrate a semiconductor package 100 according to an embodiment of the present application. FIG. 1A is a cross-sectional view of the semiconductor package 100 along the cross-section line AA′ shown in FIG. 1B. FIG. 1B illustrates a top view of the semiconductor package 100.

As shown in FIG. 1A, the semiconductor package 100 includes a substrate 110 and various components mounted on the substrate 110, such as a semiconductor die 120, an antenna block 130, and an interconnection structure 140. The antenna block 130 and the interconnection structure 140 are mounted on two different sides of the semiconductor die 120. Further, an encapsulant layer 150 is formed on the substrate 110 for encapsulating the semiconductor die 120 but exposing, at least partially, the antenna block 130 and the interconnection structure 140. In some embodiments, more than one antenna blocks can be mounted on the substrate 110 as illustrated in FIG. 1B.

In some embodiments, as shown in FIGS. 1A and 1B, the substrate 110 may be divided into three regions 101, 102 and 103. In region 101, at least one, for example three, antenna blocks 130a-130c are mounted. In region 102, the semiconductor die 120 may be mounted, preferably at a center of the region 102. In some embodiments, various electronic components 160 can also be disposed adjacent to the semiconductor die 120 in region 102. For example, electronic components 160 may surround the semiconductor die 120 or may be disposed at one or two sides of the semiconductor die 120. In region 103, at least one interconnection structure 140 is mounted for providing electrical connection from the package 100 to other electronic components. Preferably, the regions 101 and 103 are at opposite sides of region 102. That is, the antenna blocks 130a-130c and the interconnection structure 140 are at opposite sides of the semiconductor die 120. In some other embodiments, the layout of the antenna block, the semiconductor die and the interconnection structure may vary as desired. It can be understood that, the division between regions are for illustration only. Different regions may or may not have border lines. Exemplary forms and materials of the electronic components mentioned above are described below.

The substrate 110 may be a multi-layer structure, and the multi-layer structure may include multiple insulating or passivation layers and multiple conductive layers formed over or between the insulating layers. The substrate 110 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The insulating layers may contain one or more layers of silicon dioxide (SiO₂), silicon nitride (Si₃N₄), silicon oxynitride (SiON), tantalum pentoxide (Ta₂O₅), aluminum oxide (Al₂O₃), or other material having similar insulating and structural properties. The substrate 110 can also be a multi-layer flexible laminate, ceramic, copper clad laminate, glass, or semiconductor wafer including an active surface containing one or more transistors, diodes, and other circuit elements to implement analog circuits or digital circuits. The substrate 110 may include one or more electrically conductive layers or redistribution layers (RDL) formed using sputtering, electrolytic plating, electroless plating, or other suitable deposition process.

The semiconductor die 120 is mounted on the substrate 110 via for example solder bumps 121. In some embodiments, the semiconductor die 120 may include one or more digital chips, analog chips or mixed signal chips, such as application-specific integrated circuit (“ASIC”) chips, sensor chips, wireless and radio frequency (RF) chips, memory chips, logic chips or voltage regulator chips. In some embodiments, the semiconductor die 120 may include an integrated circuit chip for wireless communication and/or signal processing, which may require antennas for transmitting and receiving wireless signals. In some embodiments, the semiconductor die 120 may further include output and/or input circuits for an antenna structure for wireless communication.

The antenna blocks 130a-130c are mounted at a side of the semiconductor die 120 on the substrate 110 via for example solder bumps 131. The antenna blocks 130a-130c are used for transmitting and receiving electromagnetic signals from the external environment. A height of the antenna blocks 130a-130c can be greater than that of the semiconductor die 120. In some embodiments, each antenna block may have an antenna body 132 made of insulating or passive material, therein, antenna conductive patterns 133 can be formed for realizing the antenna function. The antenna conductive patterns 133 may be one or more layers of Al, Cu, Sn, Ni, Au, Ag, Ti, W or other suitable conductive materials. The antenna conductive patterns 133 can be formed by sputtering, electrolytic plating, electroless plating or other suitable deposition processes. It can be understood that, the antenna blocks 130a-130c may be pre-formed with any suitable technique into any desired discrete antenna structure. The antenna blocks 130a-130c may have the same or various configurations, such as the same or various frequencies. Preferably, a height difference between the antenna blocks 130a-130c may be 15%-20% of the height of the shortest antenna block. Preferably, the respective top surfaces of the antenna blocks 130a-130c may be flush with each other. In some other embodiments, as illustrated below, a high dielectric mold block may be formed on each of the antenna blocks 130a-130c. The high dielectric mold block may be preferably made of epoxy mold compound. The high dielectric mold block may be of similar material as the encapsulant layer 150. The high dielectric mold block may have a cross section of a trapezoid shape, a hemisphere shape, a semi-elliptical shape, or a lens shape. The high dielectric mold block may improve a transmission and reception rate or a gain of the respective antenna block. Preferably, a dielectric constant of the high dielectric mold block is 15-25.

Compared with the antenna blocks 130a-130c, the interconnection structure 140 is mounted at another side of the semiconductor die 120. That is, the interconnection structure 140 and the antenna blocks 130a-130c may be at adjacent or opposite sides of the semiconductor die 120. The interconnection structure 140 may be used for providing interconnection from the substrate 110 to other electronic components, such as providing board level attachment. In some embodiments, the interconnection structure 140 may be pre-solder, e-bar, Cu post, board-to-board connector, signal I/O gate with flex cable, etc. In some embodiments, the interconnection structure 140 may be formed in a same stencil printing process as the solder bumps 121, 131. It can be understood that, multiple forms of various interconnection structures 140 may be mounted on the same substrate 110.

An encapsulant layer 150 is further formed on the substrate 120 for encapsulating the semiconductor die 120 while at least partially exposing the antenna blocks 130a-130c and the interconnection structure 140. The encapsulant layer 150 may be formed with a top surface 151, and a side surface 152 extending between the top surface 151 and the interconnection structure 140. In some embodiments, the top surface 151 may be flush with a top surface of the antenna blocks 130a-130c, such that a top surface of the antenna block 130a-130c may be exposed for signal transmitting with the external environment. In some embodiments, the side surface 152 may be sloped, such that the encapsulant layer 152 may be detached from the mold chase conveniently. Preferably, the encapsulant layer 150 is formed using a film assisted molding process.

The electronic components 160 may be any discrete active or passive electronic components such as resistor, capacitor, inductor, and power metal oxide semiconductor field effect transistor (MOSFET).

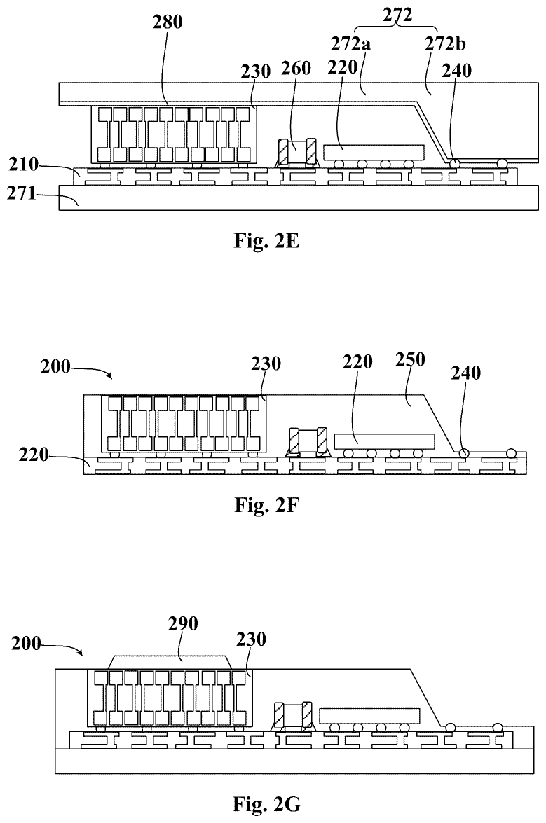

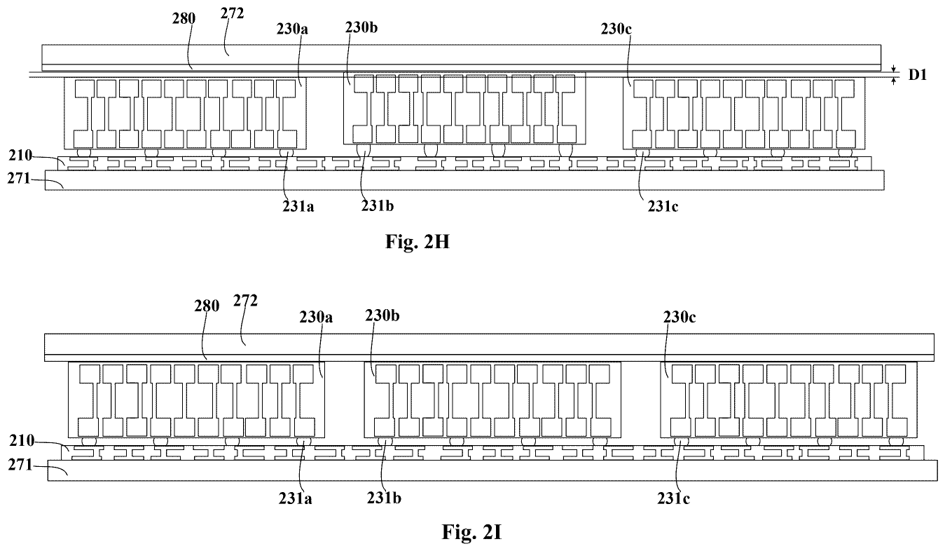

FIGS. 2A to 2G illustrate cross-sectional views of steps for forming a semiconductor package 200 along the cross-section line AA′ shown in FIG. 1B according to an embodiment of the present application. FIGS. 2H and 2I illustrate cross-sectional views of the step of pressing along the cross-section line BB′ shown in FIG. 1B.

Referring to FIG. 2A, a substrate 210 is provided. Then, electrical connection structure, such as solder bumps can be formed on the substrate 210. Referring to FIGS. 2B and 2C, in a screen-printing process, a stencil 211 can be disposed on the substrate 210, and an electrically conductive bump material can be printed at the openings of the stencil 211, forming a patterned solder layer 212. The material of the patterned solder layer 212 can be Al, Sn, Ni, Au, Ag, Pb, Bi, Cu, solder, and combinations thereof, with an optional flux solution. Preferably, the patterned solder layer 212 may include multiple solder bumps 213. Compared with the conventional AiP structure where an antenna is integrated in a cavity substrate, in the embodiments of the present application, the antenna blocks are discrete antenna blocks. Therefore, the antenna blocks can be mounted on the substrate 210 in a way similar as other electronic components, such as via solder bumps. The solder bumps for mounting the antenna blocks are at the same plane with the solder bumps for mounting other electronic components. Thus, only a 2D stencil is required, and no 3D stencil is required. Compared with the conventional AiP structure, in the embodiments of the present application, the complexity of the stencil 211 is reduced, and the efficiency of the screen-printing process can be improved.

Referring to FIG. 2D, the semiconductor die 220, the antenna block 230, and an electronic component 260 can be attached on the substrate 210 via a portion of the patterned solder layer 212-1. With a reflowing process, the portion of the patterned solder layer 212-1 can secure the semiconductor die 220, the antenna block 230 and the electronic component 260 onto the substrate 210, and also, a remaining portion of the patterned solder layer 212-2 can be transformed into interconnection structure 240. The interconnection structure 240 may take the form of solder bumps. In some other embodiments, further steps may be used for mounting other interconnection structures 240, such as board-to-board connectors, Cu posts, etc. In some embodiments, other processes such as evaporation, electrolytic plating, electroless plating, ball drop can be used for forming the interconnection structure 240.

After the steps shown above, the semiconductor die 220, the antenna block 230 and the interconnection structure 240 are mounted on the substrate 210. Then, an encapsulant layer can be formed as illustrated below.

Referring to FIG. 2E, a bottom mold chase 271 and top mold chase 272 paired with each other are provided. The bottom mold chase 271 can provide support for the substrate 210 thereon. The top mold chase 272 can have an inner surface whose shape is generally in conformity with the encapsulant layer to be formed on the substrate 210. Specifically, the top mold chase 272 may include a first chase portion 272a and a second chase portion 272b having a lower molding surface than the first chase portion 272a. As can be seen, a shape of the top mold chase 272 can be configured such that the interconnection structure 240 and the antenna block 230 are at least partially exposed from the encapsulant layer 250 to be formed, while the semiconductor die 220 is fully encapsulated. It can be understood that, in other embodiments, a shape of the mold chase may be adjusted, and therefore, an encapsulant layer formed within the mold chase may change, and a laser ablation process may follow the molding process to achieve a desired shape of the encapsulant layer to be formed.

In some embodiments, a mold release film 280 such as a polytetrafluoroethylene (PTFE) film is placed beneath the top mold chase 272 for performing a film assisted molding process. A film assisted molding process facilitates an easier release of the encapsulant layer from the top mold chase 272, especially in the case that a shape of the encapsulant layer is irregular. It can be understood that, other suitable materials can be used for the mold release film 280.

After the top and bottom mold chases 271 and 272 are provided, the substrate 210 can be disposed therebetween. Specifically, the first chase portion 272a is disposed above the antenna block 230 and the semiconductor die 220, while the second chase portion 272b is disposed above the interconnection structure 240.

In some embodiments where the encapsulant layer on a top surface of the antenna block 230 is not desired, the top mold chase 272 and the film 280 can be configured to be in close touch with a top surface of the antenna block 230, such that no gap is formed therebetween. Therefore, in the following molding process, the encapsulant material would not leak to the top surface of the antenna block 230. In some embodiments, in order to achieve the close touch between the top mold chase 272 and the antenna block 230, the top mold chase 272 and the bottom mold chase 271 may be pressed relative to each other. In such case, a mold release film 280 placed beneath the top mold chase 272 would slightly release the pressing force and thus protect a top surface of the antenna block 230 during the pressing step.

Referring to FIGS. 2H and 2I, in some embodiments, a height of top surfaces of various antenna blocks on the substrate may be different. For example, referring to FIGS. 2H, a height of the top surfaces of the antenna blocks 230a-230c on the substrate 210 may be slightly different by a distance of D1. Such height difference may be caused by a height difference of the antenna blocks itself, or, a height difference of solder bumps 231a-231c. In order to align the top surfaces of the antenna blocks 230a-230c, such that all of them may be together exposed from the encapsulant layer to be formed, a pressing step may be introduced in some embodiments of the present application before the molding process.

Specifically, the top mold chase 272 and the bottom mold chase 271 can be pressed relative to each other, therefore, the antenna blocks 230a-230c beneath the top mold chase 272 are pressed against the substrate 210, and the antenna blocks 230a-230c are aligned with each other at a same level. In such case, the mold release film 280 placed beneath the top mold chase 272 would slightly release the pressing force and thus protects a top surface of the antenna blocks 230a-230c during the pressing step.

Referring to FIGS. 2E and 2F, after the pressing step, a molding process is performed where an encapsulant material can be injected between the bottom mold chase 271 and top mold chase 272 to form the encapsulant layer 250. After the molding process, the bottom and top mold chases 271 and 272 can be removed from the substrate 220 to obtain the semiconductor package 200. As shown in FIG. 2F, in the semiconductor package 200, the top surface of the antenna block 230 is exposed, the interconnection structure 240 is partially exposed, while the semiconductor die 220 is fully encapsulated by the encapsulant layer 250.

Referring to FIG. 2G, in some embodiments, a high dielectric mold block 290 can be disposed on the antenna block 230. The high dielectric mold block 290 can increase an oblique angle transmission and reception area of the antenna block 230 underneath. A transmission and reception rate or a gain of the antenna block 230 can be improved. In some embodiments, the formation of the high dielectric mold block 290 can be after the formation of the encapsulant layer 250. In some other embodiments, as illustrated below, the high dielectric mold block and the encapsulant layer can be formed in a single molding process, such that the high dielectric mold block is integrated with the encapsulant layer.

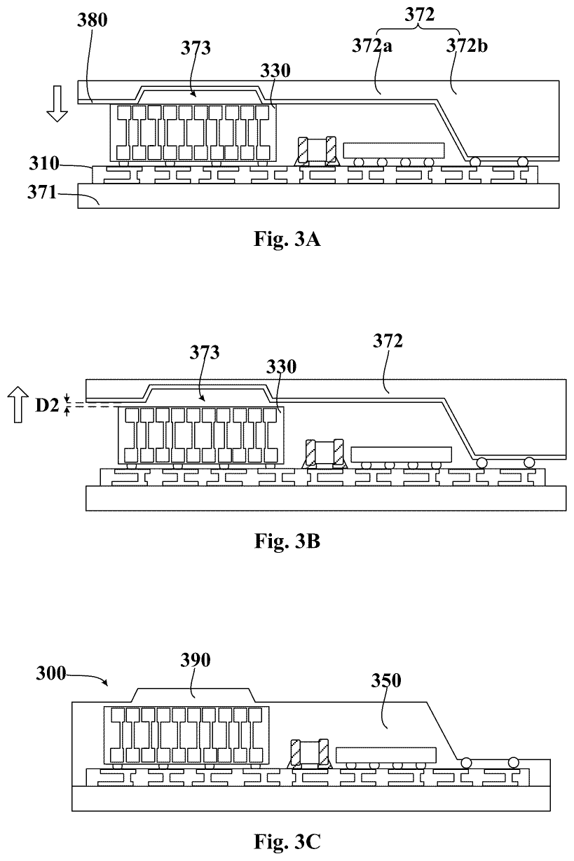

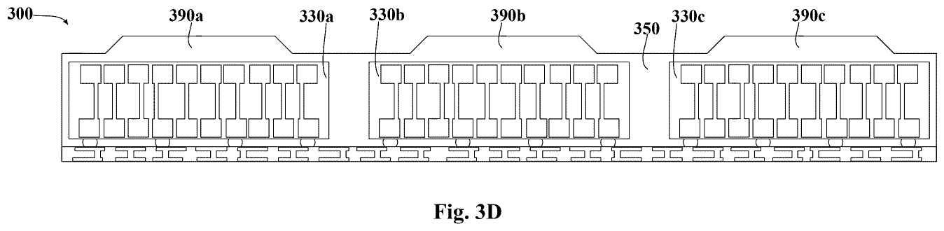

In some embodiments, multiple antenna blocks are formed in a same semiconductor package. A method for forming the semiconductor package 300 with a pressing step and a lifting step before a molding process is provided in an embodiment of the present application. FIGS. 3A to 3C illustrate cross-sectional views of steps for forming the semiconductor package 300, wherein the perspective is along the cross-section line AA′ shown in FIG. 1B. FIG. 3D illustrates a cross-sectional view of the semiconductor package 300 from the perspective along the cross-section line BB′ shown in FIG. 1B.

Referring to FIG. 3A, compared with FIG. 2E, a top mold chase 372 further includes a cavity 373 in a first chase portion 372a at a position above an antenna block 330. A shape of a second chase portion 372b may remain the same as the second chase portion 272b shown in FIG. 2E. The cavity 373 reserves a space for forming a high dielectric mold block 390 in the following molding process.

Still referring to FIG. 3A, similar as the previous embodiment, a pressing step can be performed, wherein the top mold chase 372 and a bottom mold chase 371 may be pressed relative to each other, such that heights of the antenna block(s) 330 can be aligned with each other. In some embodiments, a mold release film 380 is placed beneath the top mold chase 372, and therefore, a top surface of the antenna block 330 is protected by the mold release film 380 during the pressing step.

Referring to FIG. 3B, a lifting step is performed such that a gap with a height of D2 can be formed between the closest surfaces of the antenna block 330 and the top mold chase 372 (or the mold release film 380 if applicable). By forming the gap therebetween, in the following molding process, a molding material may flow into the cavity 373 via the gap, and thus, the encapsulant layer 350 and the high dielectric mold block 390 may be formed together in a single molding step. In some embodiments, the height of D2 may be relatively small, such that the molding material would not be undesirably thick to affect the transmission function of the antenna block 330. Exemplary material for forming the high dielectric mold block 390 and the encapsulant layer 350 includes high dielectric epoxy mold compound, etc.

Referring to FIG. 3C, in the semiconductor package 300, the high dielectric mold block 390 is connected to the encapsulant layer 350, such that both the high dielectric mold block 390 and the encapsulant layer 350 are formed in a single molding process. FIG. 3D illustrates a cross-sectional view of the semiconductor package 300 from the perspective along the cross-section line BB′ shown in FIG. 1B. It can be understood that, the pressing step facilitates that heights of respective top surface of the antenna blocks 330a-330c are the same, and the lifting step facilitates that the high dielectric mold blocks 390 may be formed with the encapsulant layer 350 in a single process. Therefore, compared with the conventional AiP structure and manufacture process, the semiconductor package and the method for forming the package according to the embodiments of the present application increases spatial efficiency, reduces manufacture complexity and increases manufacture efficiency.

The discussion herein included numerous illustrative figures that showed various portions of a semiconductor package and method of forming thereof. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package, comprising:
a substrate;
a semiconductor die mounted on the substrate;
an antenna block mounted on the substrate and at a first side of the semiconductor die, wherein the antenna block has a height greater than that of the semiconductor die;
an interconnection structure mounted on the substrate and at a second side of the semiconductor die, wherein the first side is different from the second side; and
an encapsulant layer formed on the substrate and for encapsulating the semiconductor die but exposing the antenna block and the interconnection structure.

2. The semiconductor package of claim 1, further comprising a high dielectric mold block formed on the antenna block.

3. The semiconductor package of claim 2, wherein the high dielectric mold block is formed with the encapsulant layer in a single molding process.

4. The semiconductor package of claim 1, wherein the encapsulant layer comprises a top surface and a sloped side surface extending between the top surface and the interconnection structure.

5. The semiconductor package of claim 4, wherein the top surface of the encapsulant layer is flush with a top surface of the antenna block.

6. The semiconductor package of claim 1, further comprises:
one or more additional antenna blocks mounted on the substrate and at the first side of the semiconductor die, wherein the antenna block and the one or more additional antenna blocks have respective top surfaces that are flush with each other.

7. The semiconductor package of claim 1, wherein at least a portion of the semiconductor die, the interconnection structure and the antenna block are mounted on the substrate via solder bumps using a stencil printing process.

8. The semiconductor package of claim 1, wherein the encapsulant layer is formed using a film assisted molding process.

9. The semiconductor package of claim 1, wherein the first side and the second side are opposite to each other with respect to the semiconductor die.

10. A method for forming a semiconductor package, the method comprising:
providing a substrate;
mounting a semiconductor die, an antenna block and an interconnection structure on the substrate, wherein the antenna block and the interconnection structure are at a first side and a second side of the semiconductor die, respectively, and the antenna block has a height greater than that of the semiconductor die; and
forming an encapsulant layer on the substrate to encapsulate the semiconductor die but expose the antenna block and the interconnection structure.

11. The method of claim 10, wherein mounting a semiconductor die, an antenna block and an interconnection structure comprises:
screen printing a solder material on the substrate to form a patterned solder layer;
attaching the semiconductor die and the antenna block to the substrate via a portion of the patterned solder layer; and
reflowing the patterned solder layer to secure the semiconductor die and the antenna block to the substrate via the portion of the patterned solder layer and transform a remaining portion of the patterned solder layer into the interconnection structure.

12. The method of claim 10, wherein forming an encapsulant layer comprises:
providing a top mold chase and a bottom mold chase, wherein the top mold chase comprises a first chase portion and a second chase portion having a lower molding surface than the first chase portion;
disposing the substrate between the bottom mold chase and the top mold chase, wherein the first chase portion is above the antenna block and the semiconductor die, and the second chase portion is above the interconnection structure;
pressing the top mold chase and the bottom mold chase relative to each other;
molding between the top mold chase and the bottom mold chase to form the encapsulant layer; and
removing the top mold chase and the bottom mold chase from the substrate.

13. The method of claim 10, further comprising:
forming a high dielectric mold block on the antenna block.

14. The method of claim 13, wherein forming an encapsulant layer and forming a high dielectric mold block is implemented in a single molding process.

15. The method of claim 10, wherein forming an encapsulant layer comprises forming the encapsulant layer using a film assisted molding process.

16. The method of claim 10, further comprises:
mounting one or more additional antenna blocks on the substrate and at the first side of the semiconductor die; and
pressing the antenna block and the one or more additional antenna blocks against the substrate to align top surfaces of the antenna block and the one or more additional antenna blocks with each other at a same level.
